(19) United States
(12) Patent Application Publication
(10) Pub. No.: US 2026/0190890 A1
(43) Pub. Date: Jul. 2, 2026

(54) PRE-ETCH RINSE TO ACHIEVE SILICON ETCH WITH DOPANT-TYPE SELECTIVITY

(71) Applicant: TOKYO OHKA KOGYO CO., LTD., Kawasaki-shi (JP)

(72) Inventors: Fusayo SAEKI, Beaverton, OR (US); Akira MATSUYAMA, Hillsboro, OR (US)

(21) Appl. No.: 19/420,216

(22) Filed: Dec. 15, 2025

Related U.S. Application Data
(60) Provisional application No. 63/740,113, filed on Dec. 30, 2024.

(51) Int. Cl. H10P 50/64; C09K 13/00

(52) U.S. Cl. CPC H10P 50/642; C09K 13/00

(57) ABSTRACT

A method to reduce an etch rate of n-type silicon relative to an etch rate of a collateral material, prior to an oxidative, wet-etch process, comprises exposing a surface including n-type silicon and the collateral material to an aqueous rinse of a pre-determined temperature for a pre-determined period of time.

### CROSS-REFERENCE TO RELATED APPLICATIONS

The present application claims priority to U.S. Provisional application No. 63/740,113, filed with the United States Patent and Trademark Office on Dec. 30, 2024, the entire content of which is incorporated herein by reference.

### TECHNICAL FIELD

This disclosure relates generally to the technical field of semiconductor-device fabrication and more particularly to semiconductor wet-etch processing.

### BACKGROUND

Semiconductor photolithography is a mature and sophisticated art, which is used to make integrated electronic devices of remarkable sophistication and small feature size. An elementary step in most photolithographic processing is masked etching of semiconductor or dielectric features. In masked etching, a resinous photoresist is applied over a semiconductor wafer and exposed to ultraviolet (UV) light projected through a carefully aligned, optical mask. Selected areas of the photoresist layer are either cured and thereby hardened in the pattern defined by the optical mask, or are degraded by the UV light. A solvent can then be used to remove the uncured or degraded portions of the photoresist, leaving behind a pattern of protected and unprotected areas.

Subsequent processing may vary from one implementation to another. In plasma etching, unprotected areas of the semiconductor wafer or die are subjected to high-energy reagents formed in a plasma. Such agents transform unprotected solid material into gaseous residues. In wet (i.e., solution-phase) etching, the unprotected areas are subjected to corrosive solutions that dissolve the undesired material; the soluble residues are subsequently washed away. In both implementations, subsequent processing typically requires removal of all portions of cured photoresist over the surface of the wafer or die. In wet-etch processing, a suitably formulated solvent composition may be used to that effect.

For example, Patent Document 1 (U.S. Pat. No. 11,180,697B2) discloses an etching solution suitable for the selective removal of polysilicon over silicon oxide from a microelectronic 55 device, which comprises: water; about 1 wt % of neat tetramethyl ammonium hydroxide (TMAH); about 15 wt % to about 20 wt % of monoethanolamine (MEA); about 50 wt % to about 59.5 wt % of ethylene glycol (EG); about 0.5 wt % of 8-hydroxyquinoline (8-HQ); and optionally, a surfactant.

### SUMMARY

One aspect of this disclosure relates to a method to reduce an etch rate of n-type silicon relative to an etch rate of a collateral material prior to an oxidative, wet-etch process in which the collateral material is a material that is different from n-type silicon. The method comprises exposing a surface including n-type silicon and the collateral material to an aqueous rinse of a pre-determined temperature, for a pre-determined period of time. Unless otherwise specified herein, the term “collateral material” is a material that is different from n-type silicon. The collateral material may be present on the surface to be etched. The collateral material may be adjacent or non-adjacent to n-type silicon, as long as the collateral material is present on the surface to be etched.

This Summary is provided to introduce in simplified form a selection of concepts that are further described in the Detailed Description. This Summary is not intended to identify key features or essential features of the claimed subject matter, nor is it intended to be used to limit the scope of the claimed subject matter. The claimed subject matter is not limited to implementations that solve any or all disadvantages noted in any part of this disclosure.

### BRIEF DESCRIPTION OF THE DRAWINGS

FIG. 1 schematically shows an example lateral resection of a p-type silicon (p-Si) layer.

FIG. 2 schematically shows an example removal of a p-type Si layer.

FIG. 3 shows aspects of an example method to reduce an etch rate of n-type (n-Si) silicon relative to an etch rate of a collateral material prior to an oxidative, wet-etch process.

FIGS. 4 through 6 show aspects of the application of the method of FIG. 3 to semiconductors differing with respect to layer structure and dry-etch patterning.

### DETAILED DESCRIPTION

Hereinafter, an embodiment for carrying out the present invention (hereinafter, simply referred to as “the present embodiment”) will be described in detail. The following present embodiment is an example for describing the present invention, and is not intended to limit the present invention to the following contents. The present invention can be appropriately modified and implemented within the scope of the gist thereof. In addition, the configurations and parameters disclosed in the present specification can be any combination unless otherwise specified. Furthermore, an upper limit and a lower limit of the values disclosed in the present specification can be any combination unless otherwise specified.

Wet-etch processing can provide certain advantages over plasma-etch processing for some uses in semiconductor fabrication. The operational costs may be lower, for instance, because wet-etch tools and chemicals are typically less expensive than plasma-etch tools and chemicals. In contrast to plasma-etch processing, wet-etching processing is enacted at lower temperatures, which may simplify the processing of thermally sensitive materials and structures. Wet-etch processing may also yield cleaner surfaces with less residue relative to plasma-etch processing, where residues from etchant gases and by-products may require additional cleaning protocols. In addition, wet-etching is inherently more isotropic, which can be an advantage in applications where isotropic etching is the most efficient process route to specific morphologies and/or device configurations, or for undercutting sacrificial layers.

Finally, wet-etch processing can offer high etch selectivity for one material over another in scenarios where a plurality of different materials is exposed concurrently to the same etch conditions. Available etchant solutions may etch silicon and silicon oxide, for example, at rates that differ by orders of magnitude. This feature provides functional selectivity for semiconductor etching versus dielectric etching. Other etchant solutions can discriminate between dissimilar semiconductors (e.g., germanium (Ge) versus silicon (Si)) with high selectivity. Still other etchant solutions are available that offer a 17-fold difference in etch rate on the 100 face of silicon relative to the 111 face. Such selectivity can be exploited in order to reduce the number of mask alignments and curing steps necessary in a given fabrication process and/or enable selective removal of unprotected structures, such as undercutting.

The inventors herein have sought to extend the selectivity of wet-etch processing to semiconductor systems in which the material differences between distinct, unprotected areas of a wafer or die are extremely subtle. This includes semiconductor materials presenting the same exposed crystal face but differing only in dopant type. Example approaches are illustrated herein, using silicon as the semiconductor.

Doping introduces impurities into a semiconductor. The impurities enable a space charge to develop within the doped semiconductor, which changes the Fermi level of electrons in the semiconductor relative to the valance- and conduction-band edges.

An n-type doping process adds chemical elements with more than four valence electrons into a silicon lattice. Common n-type dopants include phosphorus (P) and arsenic (As), each with five valence electrons per atom. In effect, each n-type dopant atom adds one electron to the conduction band of silicon.

Typical dopant densities for n-type Si at low to moderate dopant levels are 1015 to 1017 atoms per cubic centimeter (cm³). For many semiconductor applications, such as integrated circuits and transistors, n-type silicon is doped in this range. Typical dopant densities for n-type Si at high dopant levels are 1018 to 1020 atoms/cm³. For applications requiring high electronic conductivity, such as in certain types of power devices or specific high-speed transistors, doping concentrations in this range can be used.

A p-type doping process adds elements with fewer than four valence electrons into the silicon lattice. Common p-type dopants include boron (B), gallium (Ga), indium (In), each with three valence electrons per atom. In effect, each p-type dopant atom adds one hole to the valence band of silicon.

Typical dopant densities for p-type Si at low to moderate dopant levels are 1015 to 1017 atoms/cm³. For many semiconductor applications, such as in integrated circuits and transistors, p-type silicon is doped in this range. Typical dopant densities for p-type Si at high dopant levels are 1018 to 1020 atoms/cm³. For applications requiring high hole conductivity, such as in certain types of power devices or specific high-speed transistors, doping concentrations in this range can be used.

Dopants may be added to silicon by diffusion or by ion implantation. In diffusion the wafer is exposed to a gas containing the dopant atoms at high temperatures (typically between 800 and 1200° C.). The dopants diffuse into the silicon wafer, gradually penetrating the surface and becoming incorporated into the silicon lattice. In ion implantation dopant ions are accelerated in an electric field and directed into the silicon wafer. The ions penetrate the surface and embed themselves in the silicon lattice. This method allows for more precise control of the doping concentration and depth compared to diffusion. After the doping process, the wafer typically undergoes a thermal annealing step. Thermal annealing comprises a heating process that helps to repair the damage caused by ion implantation and activates the dopants by allowing them to occupy the expected positions in the silicon lattice.

Certain portions of a semiconductor device may comprise intrinsic silicon (i-Si), in which the concentration of conduction-band electrons is equal to the concentration of valence band holes. In some examples, silicon of this type may be very pure and not subjected to any n-type or p-type doping process (i.e., non-doped or ‘undoped’). In other examples, i-Si may be ‘intrinsically doped’, which means that n-type and p-type dopants are present in approximately equal (and typically low) concentrations, such that the Fermi level of electrons in the silicon is about the same as in non-doped silicon. The term ‘dopant type’ as used herein includes p-type, n-type, i-type, and undoped silicon.

Polycrystalline silicon (poly-Si) comprises a plurality of relatively small silicon crystals, as opposed to a wafer cut from a monocrystalline boule. In some instances, poly-Si may be used to form thin-film transistors, solar cells, as a gate material in metal-oxide-semiconductor (MOS) devices, or in flexible microelectronics.

Amorphous silicon (a-Si) is a non-crystalline form of silicon that differs from the crystalline silicon used in most semiconductor applications. Amorphous silicon lacks a long-range periodic atomic arrangement, resulting in somewhat different electrical properties relative to crystalline silicon. For instance, amorphous silicon has a larger band gap than crystalline silicon. Amorphous silicon is usually deposited as a thin film using techniques such as chemical vapor deposition (CVD) (e.g. plasma enhanced CVD (PECVD)). Amorphous silicon is often deposited in thin layers, which makes it suitable for use in flexible substrates and in various electronic devices. Generally speaking, a-Si can be doped or undoped.

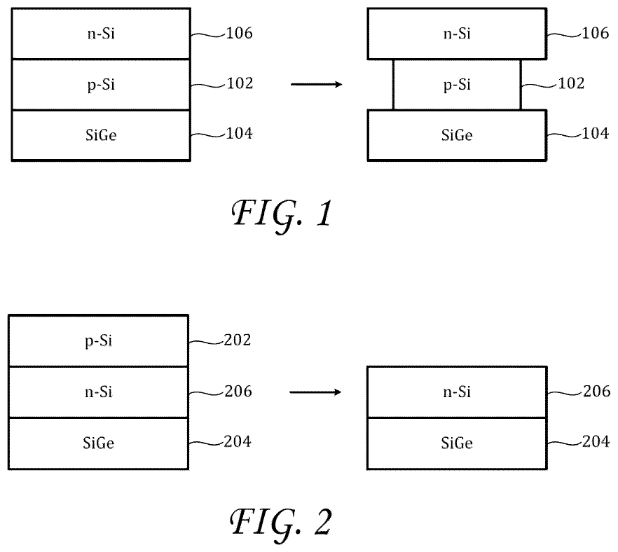

The skilled reader will appreciate that dopant densities in silicon for integrated-circuit fabrication rarely exceed 0.01% by mass. Accordingly, selective etching of p-type silicon (p-Si) in the presence of n-type silicon (n-Si), for example, is more challenging than selective etching of materials in which every etched atom is chemically distinct. Turning now to the drawings, FIGS. 1 and 2 illustrate example applications of etchant compositions and methods disclosed herein.

FIG. 1 shows aspects of an example lateral resection of an epitaxial p-Si layer 102, which is formed on an SiGe layer 104. Epitaxial n-Si layer 106, is formed on top of the epitaxial p-Si layer. The etching is achieved via wet-etch processing with p-Si and n-Si surfaces exposed concurrently to the etchant composition. As shown in the drawing, the n-Si, survives the etching with very little dimensional change, whereas the p-Si layer is significantly reduced in width.

FIG. 2 shows aspects of complete removal of an epitaxial p-Si layer 202 formed over epitaxial n-Si layer 206, which is formed on SiGe layer 204. Because the etchant composition etches p-Si much faster than it etches n-Si, layer 206 is preserved in the process. Although FIGS. 1 and 2 illustrate selective etching of epitaxial layers, that aspect is not at all necessary. In other examples, any, some or all of the layers subject to selective etching may be deposited non-epitaxially—e.g., on a glassy layer, such as amorphous SiO₂.

As noted hereinabove, wet-etch processing employs certain etchant compositions for removal of material in unprotected areas of a wafer or die. The etchant compositions are chosen based upon the rate of etching target material relative to one or more collateral materials that also may be present on the surface to be etched. In this disclosure, as explained above, the target material may be a material that is different from n-type silicon. For example, the target material may be a semiconductor of a particular dopant type or dopant level. An example collateral material may be the same semiconductor of a different dopant type or of a higher or lower dopant density of the same dopant type. Other collateral materials may include the same semiconductor presenting a different crystal face (e.g., 100 versus 111), a different semiconductor (e.g., Ge versus Si), dielectrics such as silicon oxide (SiO₂) and silicon nitride (Si₃N₄), cured photoresist (which comprises one or more cross-linked polymers), and various additive structures (e.g., metal or epitaxial semiconductor features) formed on the semiconductor wafer or die surface. Such metal features may include aluminum, copper, tungsten, molybdenum, cobalt, tantalum, and gold, among others.

TABLE 1
Effect on p-Si, poly-Si, and n-Si etch rates of rinse and etchant conditions. The etch time was 60 seconds
for all examples and comparative examples. DIW refers to de-ionized water. Cx (in which x represents
an integer of 1 to 3. For example, Cx represents C1 to C3 in Table 1.) denotes a comparative example.

| | rinse | rinse | rinse | | etchant | p-Si | poly-Si | n-Si | p-Si/n-Si | poly-Si/n-Si |
|---|---|---|---|---|---|---|---|---|---|---|
| | solution | temp | time | etchant | temp | etch rate | etch rate | etch rate | relative | relative |
| composition | (% solute) | (° C.) | (sec) | (% by mass) | (° C.) | (nm/min) | (nm/min) | (nm/min) | etch rate | etch rate |
| C1 | — | — | — | TMAH (5) | 25 | 120 | 180 | 220 | 0.5 | 0.8 |
| C2 | — | — | — | TMAH (5) | 70 | 400 | 650 | 750 | 0.5 | 0.9 |
| C3 | — | — | — | KOH (10) | 70 | 500 | 850 | 900 | 0.6 | 0.9 |
| 1 | DIW | 25 | 60 | TMAH (5) | 25 | 120 | 180 | 10 | 12 | 18.0 |
| 2 | DIW | 40 | 60 | TMAH (5) | 25 | — | 160 | 3 | — | 53.3 |
| 3 | DIW | 70 | 60 | TMAH (5) | 25 | 90 | 130 | 0.1 | 900 | 1300 |
| 4 | DIW | 70 | 60 | TMAH (5) | 40 | — | 270 | 1.2 | — | 225 |
| 5 | DIW | 70 | 60 | TMAH (5) | 70 | 340 | 520 | 7 | 48.6 | 74.3 |
| 6 | DIW | 70 | 20 | TMAH (5) | 70 | 400 | 650 | 9.1 | 44.0 | 71.4 |
| 7 | IPA (10%) | 70 | 60 | TMAH (5) | 70 | — | 570 | 1.4 | — | 407.1 |
| 8 | IPA (90%) | 70 | 10 | TMAH (5) | 70 | — | 240 | 6.5 | — | 36.9 |
| 9 | DMSO | 70 | 180 | THAH (5) | 70 | — | 550 | 2.2 | — | 250.0 |
| | (10%) | | | | | | | | | |
| 10 | NH₄OH | 70 | 180 | TMAH (5) | 70 | — | 300 | 0.1 | — | 3000 |
| | (10 ppm) | | | | | | | | | |
| 11 | HOAc | 70 | 180 | TMAH (5) | 70 | — | 550 | 25.1 | — | 21.9 |
| | (10 ppm) | | | | | | | | | |
| 12 | DIW | 70 | 60 | KOH (10) | 70 | — | 350 | 12 | — | 29.2 |

In the examples presented herein, the silicon surface that interacts with the surfactants is purposively subjected to controlled oxidation prior to interaction with the etchant compositions. The controlled oxidization is affected by brief immersion in an aqueous rinse. As used herein, the term ‘aqueous rinse’ refers to a liquid comprising water, which is applied to the surface being processed. In some examples an aqueous rinse may comprise only water (e.g., distilled or de-ionized water). In some examples an aqueous rinse may further comprise one or more solutes and/or water-miscible co-solvents dissolved in the water, as described further below. Accordingly, an aqueous rinse may comprise a aqueous rinse solution. In some examples water may be the primary component of an aqueous rinse; in other examples the proportion of water in an aqueous rinse may not be primary. For example, in one of the preferred examples where water is the main component of the aqueous rinse, the proportion of water is preferably 50% by mass or more, more preferably 60% by mass or more, even more preferably 70% by mass or more, even more preferably 80% by mass or more, and even more preferably 90% by mass or more. Alternatively, in some examples where the proportion of water in the aqueous rinse is not primary, the proportion of water in an aqueous rinse can be 10% by mass or lower, and the primary component may be a water-miscible organic solvent. Thus, the term ‘aqueous rinse’ represents any rinse to which a quantity of water is added as a formulation. In some instances, the term ‘rinse’ is herein synonymous with ‘aqueous rinse’. Although neutral, acidic, and basic aqueous rinses are envisaged in this disclosure, an aqueous rinse comprises no hydrogen fluoride (HF) under acidic conditions.

Oxide formed on any type of silicon by immersion in an aqueous rinse reduces the subsequent etch rates on the silicon. The overall effect on the etch rate may differ, however, depending on the dopant type of the silicon. It is plausible that the rate of oxide growth as well as the final etch rate may be dopant-sensitive. Results are summarized in Table 1.

In the examples and comparative examples of Table 1 an oxide-etched surface including n-type silicon or a collateral material is exposed to a rinse of a pre-determined temperature, for a pre-determined period of time. Immediately following the rinse exposure, the surface is exposed to a basic etchant composition of a pre-determined temperature, for a pre-determined period of time. In the tabulated examples the ‘collateral material’ is silicon of a dopant type that differs from n-Si (e.g., p-Si or poly-Si). In other examples a collateral material may include a metal, such as any metal used to make ohmic contact on silicon patterned or unpatterned silicon structures. In still other examples a collateral material may include a dielectric, such as SiO₂ or Si₃N₄. Accordingly, in some examples the collateral material may include a metal or a dielectric.

Rinse-and-etch processing using example conditions 1 through 12 of Table 1 each offer an etch rate on silicon which is sensitive to the dopant type of the silicon. The sensitivity to dopant type is revealed in the seventh (7th) through eleventh (11th) columns of Table 1. The seventh (7th) column lists the etch rate in nm/min on p-Si, the eighth (8th) column lists the corresponding etch rate on poly-Si, and the ninth (9th) column lists the corresponding etch rate on n-Si. The tenth (10th) and eleventh (11th) columns show the ratios of these rates.

The etch rates appearing in Table 1 were determined in the following manner. Epitaxial films of n-Si and p-Si were grown via chemical vapor deposition (CVD) on silicon-germanium (SiGe) wafers. Films of poly-Si were grown via CVD on SiO₂ substrates. Each film-coated wafer was divided into a plurality of test samples of about 1 to 10 square centimeters. For each test sample, the film thickness was measured via ellipsometry or x-ray fluorescence (XRF).

For each test sample, 100 milliliters (mL) of aqueous hydrogen fluoride (HF, 0.5% by mass) was dispensed into a first plastic cup and stirred magnetically at 300 revolutions per minute (rpm) at 25° C. The same volume of etchant composition was dispensed into a second plastic cup and stirred magnetically at 300 rpm, at the temperature indicated in the fifth (5th) column of Table 1. Into third and fourth plastic cups was dispensed 100 mL of a rinse comprising de-ionized water, and optionally one or more organic solvents. The rinse was stirred magnetically at 300 rpm at the temperature indicated in the third column of Table 1. Each test sample was placed in the first cup for 60 seconds, then moved to the third cup for the time indicated in the fourth column of Table 1, then to the second cup for 60 seconds, and then to the fourth cup for 5 seconds. The samples were then dried and the film-thickness measurement by ellipsometer or XRF was repeated.

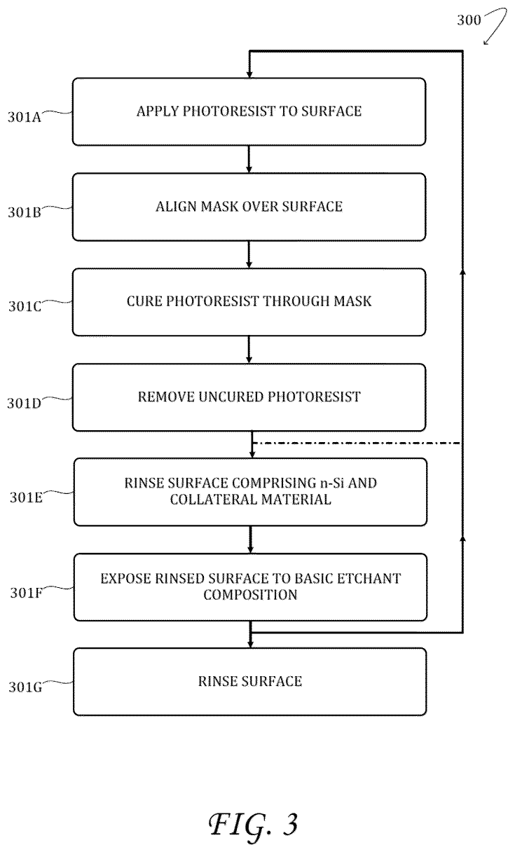

FIG. 3 shows aspects of an example method 300 to reduce an etch rate of n-type silicon relative to an etch rate of a collateral material prior to an oxidative, wet-etch process. In some examples the collateral material may include one or more of p-type silicon, poly-silicon, or amorphous silicon. In addition, in some examples the collateral material may include one or more of p-type silicon, undoped silicon, poly-silicon, or amorphous silicon In these and other examples the collateral material may include a metal or a dielectric, as noted hereinabove.

At 301A of method 300 a photoresist is applied to the surface. At 301B a mask is aligned over the surface. At 301C the photoresist is cured by UV exposure through the mask. At 301D the uncured photoresist is removed from the surface.

At 301E the surface which includes the n-type silicon and the collateral material is exposed to an aqueous rinse of a pre-determined temperature, for a pre-determined period of time. In some examples the rinse may include greater than 90% water. In some variants of method 300 the rinse exposure is a dip exposure (i.e., an immersion). In other variants the rinse exposure is a spray or continuous-flow exposure.

In some examples the rinse comprises a base. The base may comprise ammonium hydroxide or another weak base, for instance. In other examples the rinse may comprise an acid. The acid may comprise acetic acid or another acid, for instance. In some examples the rinse may comprise a pH buffer, which sets the pH of the rinse to any suitable value. In some examples the rinse may comprise no hydrogen fluoride under acidic conditions.

In some examples the rinse may further comprise an organic solvent. For example, rinse may water and an organic solvent. Furthermore, the rinse may further comprise a water-miscible organic solvent. The organic solvent may include 2-propanol (IPA) or dimethylsulfoxide (DMSO), for instance. Other water-miscible organic solvents, such as polar protic and aprotic solvents may also be used. Such solvents may include methanol, ethanol, acetone, acetonitrile, or tetrahydrofuran (THF), as examples. In some examples the rinse may comprise a cationic, anionic, or non-ionic surfactant.

In some examples the pre-determined temperature of the rinse is preferably greater than 10° C. In some examples the pre-determined period of time of exposure of the surface to the rinse is preferably greater than 5 seconds. Temperature and exposure times outside of these ranges are also envisaged.

At 301F the rinsed surface is exposed to a basic etchant composition. Again, dip exposure, spray exposure, and continuous-flow exposure are envisaged, among other modes of exposure. In some examples the basic etchant composition comprises a quaternary ammonium hydroxide, such as tetramethylammonium hydroxide (TMAH), tetraethylammonium hydroxide (TEAH), tetra-n-butylammonium hydroxide, etc. In some examples the basic etchant composition may comprise an alkali-metal hydroxide, such as NaOH or KOH. In some examples, the basic etchant composition may comprise 4-dimethylaminopyridine, 1,2-ethylenediamine, 1,3-dimethylbutylamine, triethanolamine, n-butylamine, N,N-diethylhydroxylamine (DEHA), 2,5-dimethyl-2,5-hexanediol (DMHD), triethylenetetramine (TETA), tris(2-aminoethyl)amine (TAEA), and/or diethylenetriamine (DETA), among others. In some examples, the basic etchant composition may comprise an alcohol or a poly-ol, such as 1-butanol, 1,2-heptanediol, among others. In some examples, the basic etchant composition may comprise one or more organic solvents, such as methanol, ethanol, IPA, n-butanol, cyclic ethers, alcohol ethers, acetone, acetonitrile, DMSO, DMF, propylene carbonate (PC), and/or propylene glycol methyl ether acetate (PGMEA). In some examples the basic etchant composition may comprise one or more nonionic, anionic, or cationic surfactants.

In some implementations of method 300, the process flow returns from 301F back to 301A for one or more additional mask-rinse-etch iterations. In some implementations the process flow returns from 301F back to 301E. Accordingly, method 300 also embodies a method to reduce an etch rate of n-type silicon relative to an etch rate of a collateral material subsequent to an oxidative, wet-etch process. In some specific examples of such method may include: a method to reduce an etch rate of n-type silicon relative to an etch rate of a collateral material subsequent to an oxidative, wet-etch process, the method comprising exposing an etched surface of n-type silicon and the collateral material to a rinse of a pre-determined temperature for a pre-determined period of time. In some examples of these methods, the method preferably comprises exposing the surface to a basic etchant composition. In some examples of these methods, the collateral material preferably includes one or more of p-type silicon, poly-silicon, amorphous silicon, a metal, or a dielectric. In some examples of these methods, the rinse preferably comprises greater than ninety-nine percent (99%) water. In some examples of these methods, the rinse preferably comprises a base. In some examples of these methods, the pre-determined temperature is preferably greater than 10° C., wherein the pre-determined period of time is preferably greater than 5 seconds, and wherein the rinse comprises no hydrogen fluoride under acidic conditions.

At 301G the surface undergoes a final rinse. In some examples the rinsing agent may comprise water. In some examples the rinsing agent may comprise an alcohol, such as methanol, ethanol, or IPA. Optionally, after the surface is rinsed and suitably dried, one or more dry-etch processes may be enacted, as desired. Optionally, the cured photoresist may be removed at this point.

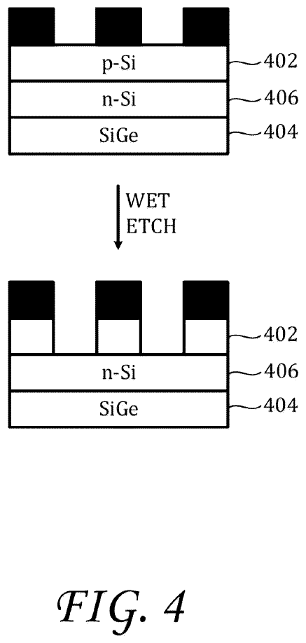

Method 300 may be used to form various types of microstructures on a semiconductor surface, such as the surface of a layered and/or patterned semiconductor. In some scenarios, the result of the application of method 300 depends upon the initial layer structure and on whether any additional etch processes, such as a dry etch, is also employed. FIGS. 4 through 6 illustrate this feature by way of example. In each drawing the starting structure includes a pattern of cured photoresist (shown in black), as would be present following step 301D of method 300.

In the structure shown in FIG. 4 an n-Si layer 406 is formed on SiGe layer 404. A p-Si layer 402 is formed on top of the n-Si layer. Due to the rinse enacted at 301E, which imparts dopant-type selectivity to the subsequent wet etch (favoring p-Si etching relative to n-Si etching), the wet etch penetrates the p-Si layer and stops at the p-Si/n-Si boundary, effectively. Although n-Si is exposed to the etchant composition as the etch proceeds vertically downward, very limited etching of the n-Si occurs.

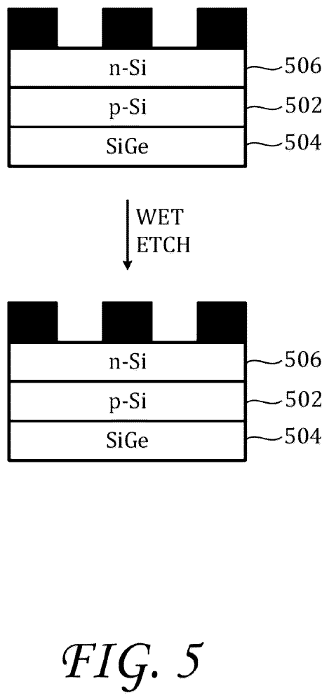

In the structure shown in FIG. 5 a p-Si layer 502 is formed on SiGe layer 504. An n-Si layer 506 is formed on top of the p-Si layer. The rinse enacted at 301E imparts dopant-type selectivity to the subsequent wet etch (favoring p-Si etching relative to n-Si etching). As none of the p-Si is exposed to the etchant composition, however, very limited etching occurs.

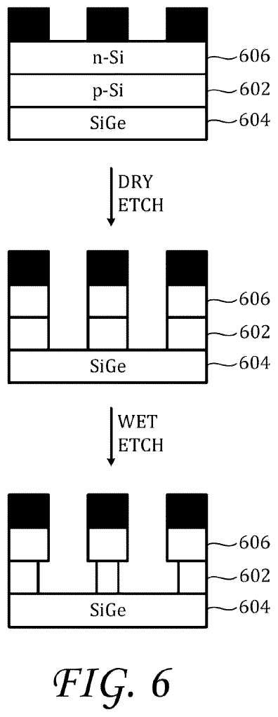

The initial structure in FIG. 6 is the same as in FIG. 5: a p-Si layer 602 is formed on SiGe layer 604. An n-Si layer 606 is formed on top of the p-Si layer. In this example, however, an anisotropic dry etch is enacted before the dopant-selective wet etch. The anisotropic dry etch etches the layer structure to the SiGe layer 604. Due to the rinse enacted at 301E, which imparts dopant-type selectivity to the subsequent wet etch (favoring p-Si etching relative to n-Si etching), the subsequent wet etch acts laterally on the exposed p-Si in preference to the exposed n-Si.

No aspect of this disclosure should be interpreted in a limiting sense, for numerous variations, extensions, and omissions are equally envisaged. For instance, while the method of FIG. 3 illustrates selective etching after circuit patterning, selective etching according to the methods herein may also be useful before patterning or in between separate patterning procedures. Although the foregoing description refers specifically to etchant compositions with selectivity based on dopant type, the same or similar etchant compositions may show etch-rate selectivity based on dopant density—e.g., normal dopant density versus high dopant density versus degenerate doping. Moreover, the same or similar etchant compositions may show etch-rate sensitivity based on dopant depth—e.g., deep doping versus shallow doping.

Again, while no aspect of this disclosure is tied to any particular theory, it may be the case that the primary chemical effect of the dopant type and dopant density is to influence the space charge that develops within the semiconductor material when the semiconductor surface comes to electrostatic equilibrium with the etchant composition. Such equilibrium causes charge to accumulate, dependent on the dopant type, dopant density, and dopant depth, at the interface between the semiconductor surface and the solution. It is plausible that the relative etch rates reported in this disclosure as a function of dopant type are due to the changes in surface chemistry that result from the accumulated surface charge and are therefore extensible to dopant depth and to dopant density.

This disclosure is presented by way of example and with reference to the attached drawing figures. Components, process steps, and other elements that may be substantially the same in one or more of the figures are identified coordinately and described with minimal repetition. It will be noted, however, that elements identified coordinately may also differ to some degree. It will be further noted that the figures are schematic and generally not drawn to scale. Rather, the various drawing scales, aspect ratios, and numbers of components shown in the figures may be purposely distorted to make certain features or relationships easier to see. In addition, some overlapping explanations of the drawing figures have been omitted.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed. In some examples the terms ‘about’ and ‘approximately’, as applied to a numeric value x, expand x to include any value in a range between 0.9x and 1.1x; in some examples these terms expand x to include any value in a range between 0.95x and 1.05x.

In addition, the configurations and parameters disclosed in the present specification can be any combination unless otherwise specified. Furthermore, an upper limit and a lower limit of the values disclosed in the present specification can be any combination unless otherwise specified. In addition, in the present specification, the term “comprise” or “contain” may be replaced with “consist essentially of” and “consist of” as necessary. Further, the expression “A and/or B” means “A, B, or both”, unless otherwise specified. In the present specification, the terms “parts by mass” or “% by mass” are used, unless otherwise specified. In the present specification, the term “amount used” may refer to the content, and the term “content” may refer to the amount used.

The subject matter of the present disclosure includes all novel and non-obvious combinations and sub-combinations of the various processes, systems and configurations, and other features, functions, acts, and/or properties disclosed herein, as well as any and all equivalents thereof.

Note that, in the present specification, the expression “doing something or to do something” may refer to “process” or “step”, “process” may refer to “doing something or to do something” or “step”, and “step” may refer to “doing something or to do something” or “process”. In addition, in the present specification, the term “process” such as “step” may refer to “apparatus or unit that is configured to perform the step”, the term “apparatus” may refer to “mechanism or unit”, and the term “unit” may refer to “unit or apparatus provided for a mechanism, an apparatus, or a system”.

This disclosure also includes embodiments exemplified below.
<1> A method to reduce an etch rate of n-type silicon relative to an etch rate of a collateral material prior to an oxidative, wet-etch process, the method comprising:
exposing a surface including n-type silicon and the collateral material to an aqueous rinse of a pre-determined temperature for a pre-determined period of time.
<2> The method of <1> further comprising exposing the surface to a basic etchant composition.
<3> The method of <1> wherein the basic etchant composition comprises a quaternary ammonium hydroxide.
<4> The method of <1> wherein the collateral material includes one or more of p-type silicon, undoped silicon, poly-silicon, or amorphous silicon.
<5> The method of <1> wherein the collateral material includes a metal or dielectric.
<6> The method of <1> wherein the rinse comprises greater than ninety-nine percent water.
<7> The method of <6> wherein the rinse further comprises an organic solvent.
<8> The method of <1> wherein the rinse comprises a base.
<9> The method of <8> wherein the base comprises ammonium hydroxide.
<10> The method of <1> wherein the rinse comprises an acid.
<11> The method of <1> wherein the pre-determined temperature is greater than 10° C.
<12> The method of <1> wherein the pre-determined period of time is greater than 5 seconds.
<13> The method of <1> wherein the rinse comprises no hydrogen fluoride under acidic conditions.
<14> A method to reduce an etch rate of n-type silicon relative to an etch rate of a collateral material subsequent to an oxidative, wet-etch process, the method comprising: exposing an etched surface of n-type silicon and the collateral material to a rinse of a pre-determined temperature for a pre-determined period of time.
<15> The method of <14> further comprising exposing the surface to a basic etchant composition.
<16> The method of <14> wherein the collateral material includes one or more of p-type silicon, poly-silicon, amorphous silicon, a metal, or a dielectric.
<17> The method of <14> wherein the rinse comprises greater than ninety-nine percent water.
<18> The method of <14> wherein the rinse comprises a base.
<19> The method of <14> wherein the pre-determined temperature is greater than 10° C., wherein the pre-determined period of time is greater than 5 seconds, and wherein the rinse comprises no hydrogen fluoride under acidic conditions.

1. A method to reduce an etch rate of n-type silicon relative to an etch rate of a collateral material prior to an oxidative, wet-etch process, the method comprising:
exposing a surface including n-type silicon and the collateral material to an aqueous rinse of a pre-determined temperature for a pre-determined period of time.

2. The method of claim 1 further comprising exposing the surface to a basic etchant composition.

3. The method of claim 1 wherein the basic etchant composition comprises a quaternary ammonium hydroxide.

4. The method of claim 1 wherein the collateral material includes one or more of p-type silicon, undoped silicon, poly-silicon, or amorphous silicon.

5. The method of claim 1 wherein the collateral material includes a metal or dielectric.

6. The method of claim 1 wherein the rinse comprises greater than ninety-nine percent water.

7. The method of claim 6 wherein the rinse further comprises an organic solvent.

8. The method of claim 1 wherein the rinse comprises a base.

9. The method of claim 8 wherein the base comprises ammonium hydroxide.

10. The method of claim 1 wherein the rinse comprises an acid.

11. The method of claim 1 wherein the pre-determined temperature is greater than 10° C.

12. The method of claim 1 wherein the pre-determined period of time is greater than 5 seconds.

13. The method of claim 1 wherein the rinse comprises no hydrogen fluoride under acidic conditions.

14. A method to reduce an etch rate of n-type silicon relative to an etch rate of a collateral material subsequent to an oxidative, wet-etch process, the method comprising:
exposing an etched surface of n-type silicon and the collateral material to a rinse of a pre-determined temperature for a pre-determined period of time.

15. The method of claim 14 further comprising exposing the surface to a basic etchant composition.

16. The method of claim 14 wherein the collateral material includes one or more of p-type silicon, poly-silicon, amorphous silicon, a metal, or a dielectric.

17. The method of claim 14 wherein the rinse comprises greater than ninety-nine percent water.

18. The method of claim 14 wherein the rinse comprises a base.

19. The method of claim 14 wherein the pre-determined temperature is greater than 10° C., wherein the pre-determined period of time is greater than 5 seconds, and wherein the rinse comprises no hydrogen fluoride under acidic conditions.
